(19) United States
(12) Patent Application Publication
(10) Pub. No.: US 2025/0324630 A1
(43) Pub. Date: Oct. 16, 2025

(54) HIGH ELECTRON MOBILITY TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Randy L. Yach, Phoenix, AZ (US)

(73) Assignee: Microchip Technology Incorporated, Chandler, AZ (US)

(21) Appl. No.: 18/924,073

(22) Filed: Oct. 23, 2024

Related U.S. Application Data
(60) Provisional application No. 63/634,296, filed on Apr. 15, 2024.

(51) Int. Cl. H01L 29/66; H01L 29/20; H01L 29/423; H01L 29/778

(52) U.S. Cl. CPC H10D 30/015; H10D 30/475; H10D 62/8503; H10D 64/411

(57) ABSTRACT

A High-Electron-Mobility-Transistor having a first barrier layer formed on a first buffer layer formed on a substrate. A second barrier layer having a recessed portion and an upper portion formed over the first barrier layer. A doped structure formed on the first barrier layer and surround by the second barrier layer. A second buffer layer formed over the recessed portion and the upper portion of the second barrier layer. A spacer formed on a portion of the doped structure. An insulating layer formed over the second buffer layer. A gate electrode formed within the spacer through the insulating layer, through the second buffer layer and partially into the upper portion of the second barrier layer. A drain terminal formed at a first side of the gate electrode. A source terminal formed at a second side of the gate electrode.

### CROSS-REFERENCE TO RELATED APPLICATION

The present application claims priority to U.S. Provisional Patent Application No. 63/634,296, filed on Apr. 15, 2024, the contents of which are hereby incorporated by reference in their entirety.

### TECHNICAL FIELD

The present disclosure relates high electron mobility transistors (HEMTs), and more specifically to high performance HEMTs and methods for manufacturing same to improve the drive current and to reduce the leakage current of the HEMT.

### SUMMARY

According to an aspect of one or more examples, there is provided a High-Electron-Mobility-Transistor that may include a substrate, a first buffer layer formed on the substrate, a first barrier layer formed on the first buffer layer, a doped structure formed on the first barrier layer, a second barrier layer having a recessed portion and an upper portion, the second barrier layer formed over the first barrier layer and formed over the doped structure, wherein the second barrier layer surrounds the doped structure, a second buffer layer formed over the recessed portion of the second barrier layer and formed over the upper portion of the second barrier layer, a spacer formed on a portion of the doped structure through the second buffer layer and through the upper portion of the second barrier layer, an insulating layer formed over the second buffer layer and formed over a portion of the spacer, a gate electrode formed within the spacer through the insulating layer, through the second buffer layer and partially into the upper portion of the second barrier layer, the gate electrode connected to the doped structure, a drain terminal formed at a first side of the gate electrode, and a source terminal formed at a second side of the gate electrode. The substrate may comprise gallium nitride, diamond, silicon carbide, sapphire, aluminum nitride or silicon. The first buffer layer may comprise a first III-V compound semiconductor such as gallium nitride. The first barrier layer may comprise aluminum gallium nitride. The second barrier layer may comprise aluminum gallium nitride. The doped structure may comprise P-doped gallium nitride. The second buffer layer may comprise a second III-V compound semiconductor such as gallium nitride. The insulating layer may comprise polysilicon, silicon dioxide or a mixture of polysilicon and silicon dioxide.

According to an aspect of one or more examples, there is provided method for producing a High-Electron-Mobility-Transistor. The method may include providing a substrate, forming a first buffer layer on the substrate, forming a first barrier layer over the first buffer layer, forming a doped structure over the first barrier layer, forming a second barrier layer having a recessed portion and an upper portion, the second barrier layer formed over the first barrier layer and formed over the doped structure, wherein the second barrier layer surrounds the doped structure, forming a second buffer layer over the recessed portion of the second barrier layer and over the upper portion of the second barrier layer, forming a spacer on a portion of the doped structure through the second buffer layer and through the upper portion of the second barrier layer, forming an insulating layer over the second buffer layer and over a portion of the spacer, forming a gate electrode within the spacer through the insulating layer, through the second buffer layer and partially into the upper portion of the second barrier layer, the gate electrode connected to the doped structure, forming a drain terminal at a first side of the gate electrode, and forming a source terminal formed at a second side of the gate electrode. The substrate may comprise gallium nitride, diamond, silicon carbide, sapphire, aluminum nitride or silicon. The first buffer layer may comprise a first III-V compound semiconductor such as gallium nitride. The first barrier layer may comprise aluminum gallium nitride. The second barrier layer may comprise aluminum gallium nitride. The doped structure may comprise P-doped gallium nitride. The second buffer layer may comprise a second III-V compound semiconductor such as gallium nitride. The insulating layer may comprise polysilicon, silicon dioxide or a mixture of polysilicon and silicon dioxide.

### BRIEF DESCRIPTION OF DRAWINGS

FIG. 1 is a cross sectional view of a High-Electron-Mobility-Transistor according to one or more examples;

FIG. 2A is cross sectional view of some of the steps in a method of manufacturing a High-Electron-Mobility-Transistor according to one or more examples;

FIG. 2B is cross sectional view of some of the steps in a method of manufacturing a High-Electron-Mobility-Transistor according to one or more examples;

FIG. 2C is cross sectional view of some of the steps in a method of manufacturing a High-Electron-Mobility-Transistor according to one or more examples;

FIG. 2D is cross sectional view of some of the steps in a method of manufacturing a High-Electron-Mobility-Transistor according to one or more examples;

FIG. 2E is cross sectional view of some of the steps in a method of manufacturing a High-Electron-Mobility-Transistor according to one or more examples; and

FIG. 2F is cross sectional view of some of the steps in a method of manufacturing a High-Electron-Mobility-Transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

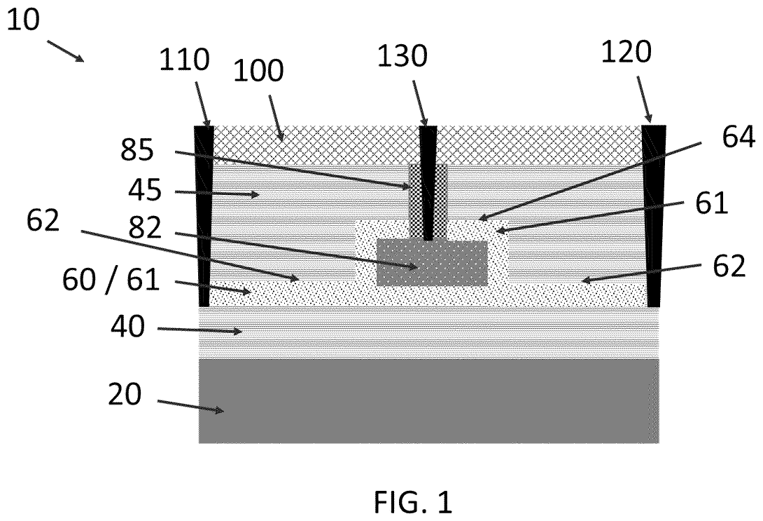

FIG. 1 shows a cross sectional view of a High-Electron-Mobility-Transistor 10 according to one or more examples. As shown in FIG. 1, the High-Electron-Mobility-Transistor 10 may include a substrate 20 with a first buffer layer 40 formed on the substrate 20. The substrate 20 may comprise gallium nitride, diamond, silicon carbide, sapphire, aluminum nitride or silicon. The first buffer layer 40 may comprise a first III-V compound semiconductor such as gallium nitride. A first barrier layer 60 may be formed on the first buffer layer 40. The first barrier layer 60 may comprise aluminum gallium nitride. A doped structure 82 may be formed on the first barrier layer 60. The doped structure 82 may comprise P-doped gallium nitride. A second barrier layer 61 may be formed over the first barrier layer 60 and may be formed over the doped structure 82. The second barrier layer 61 may have a recessed portion 62 and an upper portion 64. The second barrier layer 61 may surround the doped structure 82. A second buffer layer 45 may be formed over the recessed portion 62 of the second barrier layer 61 and may be formed over the upper portion 64 of the second barrier layer 61. The second buffer layer 45 may comprise a second III-V compound semiconductor such as gallium nitride. Due to the nature of gallium nitride/aluminum gallium nitride band bending a 2DEG (Two-Dimensional Electron Gas) may be formed at the interface of these two materials (i.e., the first buffer layer 40 and the barrier layer 60 as well as the second buffer layer 45 and the second barrier layer 61). This is like electron gas that is free to move in two dimensions and confined in the third dimension. A spacer 85 may be formed over a portion of the doped structure 82 through the second buffer layer 45 and through the upper portion 64 of the second barrier layer 61. An insulating layer 100 may be formed over the second buffer layer 45 and may be formed over a portion of the spacer 85. The insulating layer 100 may comprise polysilicon, silicon dioxide or a mixture of polysilicon and silicon dioxide or any other insulating material or a mixture of all these. The insulating layer 100 may comprise an insulator having a K value between 1 to 3.9. A gate electrode 130 formed within the spacer 85 through the insulating layer 100, through the second buffer layer 45 and partially into the upper portion 64 of the second barrier layer 61. The gate electrode 130 may be connected to the doped structure 82. A drain terminal 120 may be formed at a first side of the gate electrode 130. A source terminal 110 may be formed at a second side of the gate electrode 130.

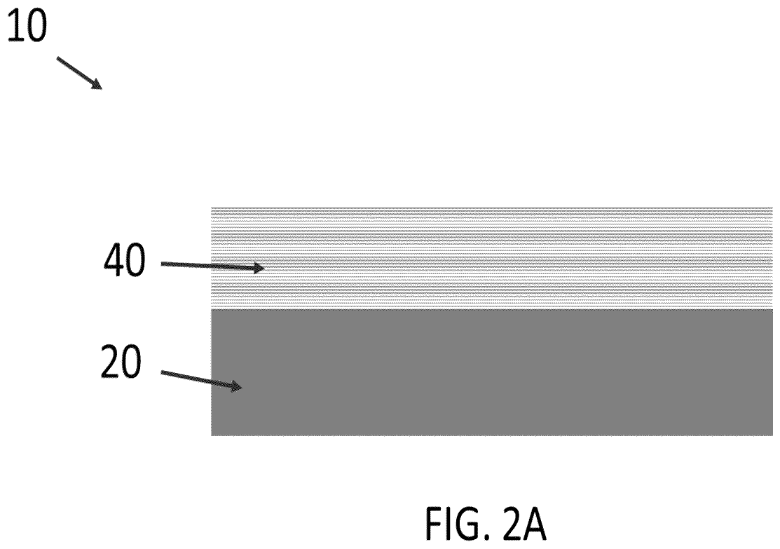

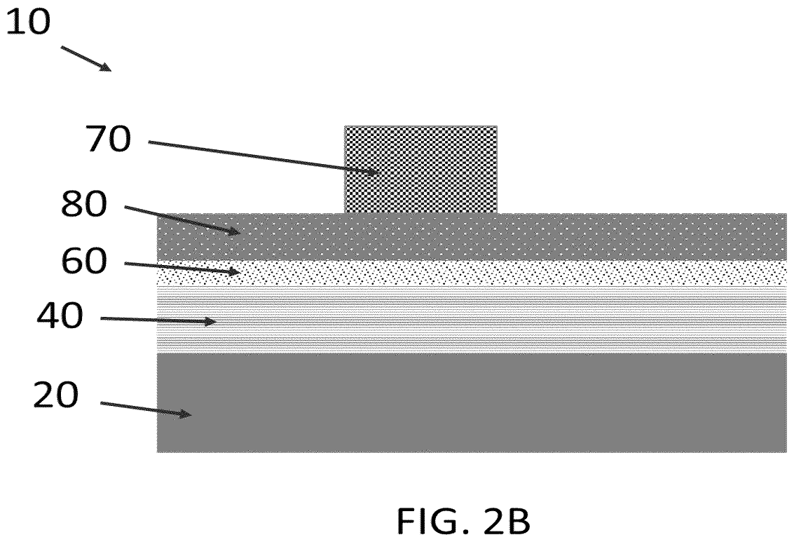

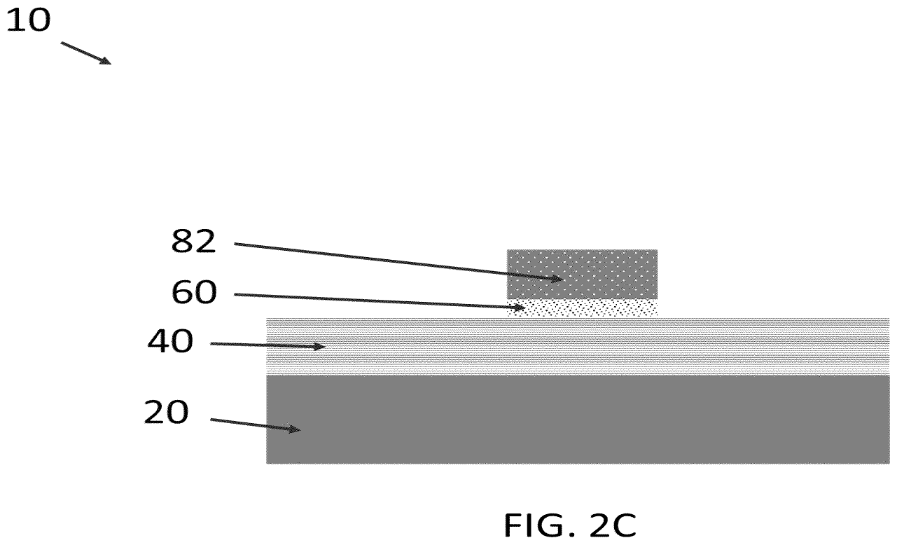

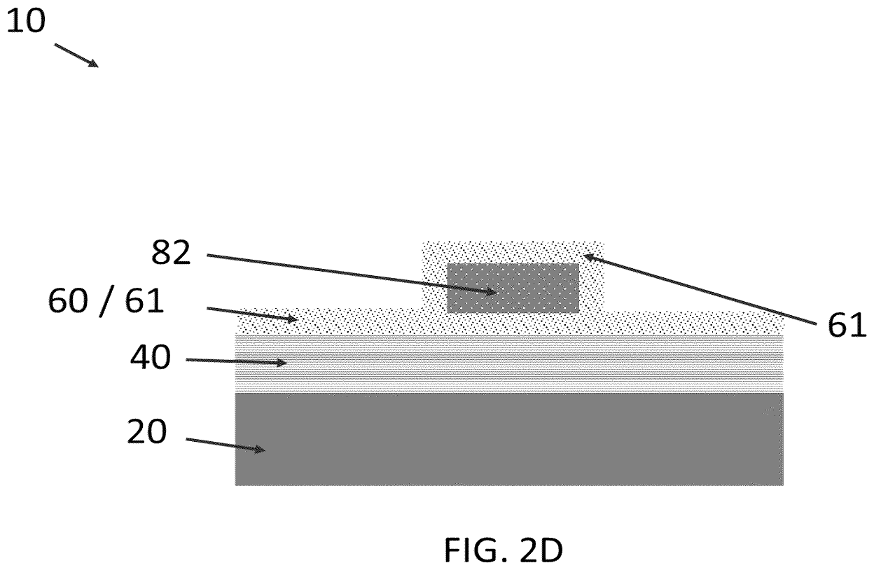

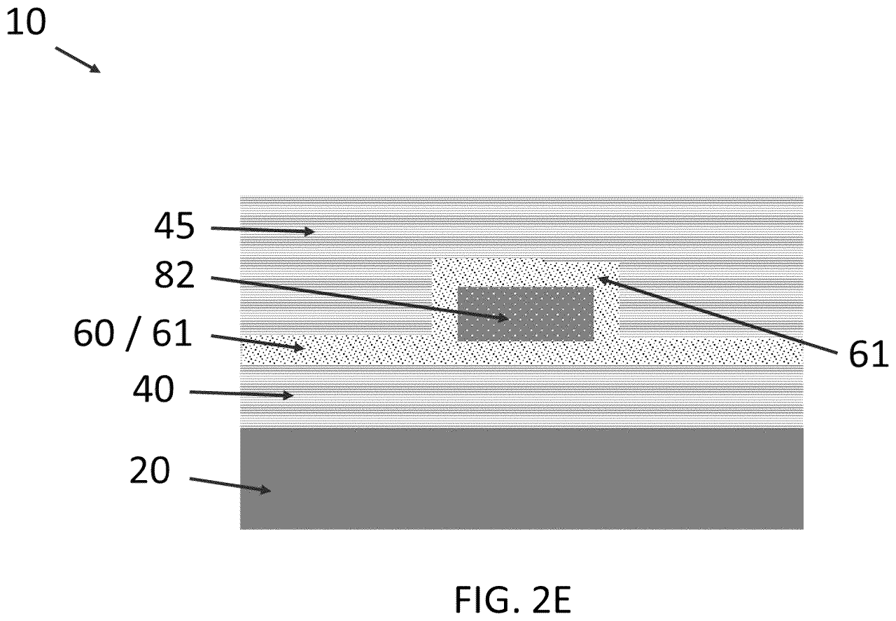

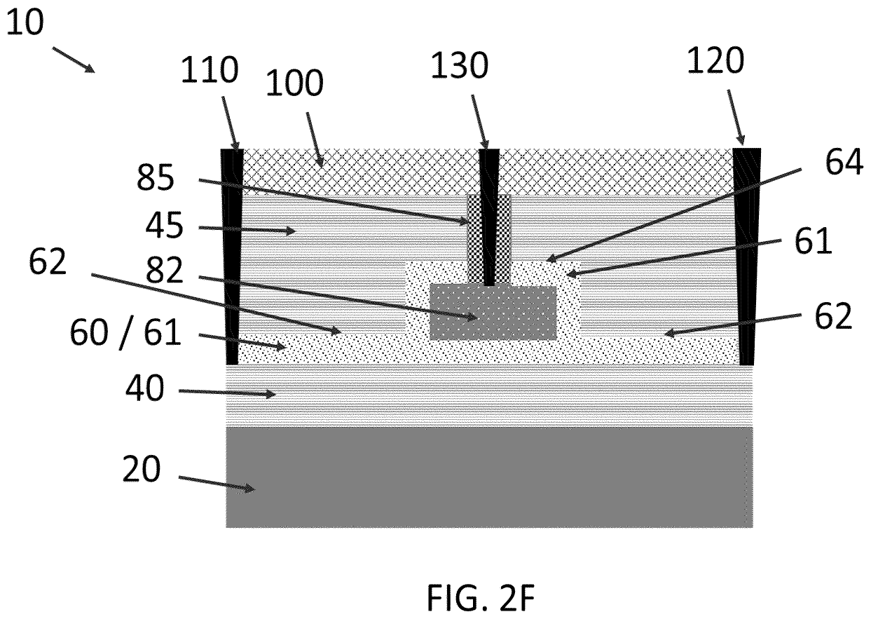

FIGS. 2A-2F show a method of manufacturing a High-Electron-Mobility-Transistor 10 according to one or more examples. Although the example method shown in FIGS. 2A-2F includes steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A show is cross sectional view of some of the steps in a method of manufacturing a High-Electron-Mobility-Transistor 10 according to one or more examples. In FIG. 2A, the example method may include forming a first buffer layer 40 on a substrate 20. The first buffer layer 40 may comprise a first III-V compound semiconductor such as gallium nitride. The substrate 20 may comprise gallium nitride, diamond, silicon carbide, sapphire, aluminum nitride or silicon.

FIG. 2B is cross sectional view of some of the steps in a method of manufacturing a High-Electron-Mobility-Transistor 10 according to one or more examples. In FIG. 2B, the example method may include forming a first barrier layer 60 over the first buffer layer 40. The first barrier layer 60 may comprise aluminum gallium nitride. In FIG. 2B, the example method may include forming a doped layer 80 over the first barrier layer 60. The doped layer 80 may comprise P-doped gallium nitride. In FIG. 2B, the example method may include forming a gate mask 70 over the doped layer 80.

FIG. 2C is cross sectional view of some of the steps in a method of manufacturing a High-Electron-Mobility-Transistor 10 according to one or more examples. In FIG. 2C, the example method may include forming the doped layer 80 of FIGS. 2A and 2B into a doped structure 82. The doped structure 82 may comprise P-doped gallium nitride.

FIG. 2D is cross sectional view of some of the steps in a method of manufacturing a High-Electron-Mobility-Transistor 10 according to one or more examples. In FIG. 2D, the example method may include forming a second barrier layer 61 onto exposed surfaces of the first barrier layer 60 and may be formed over the doped structure 82. The second barrier layer 61 may have a recessed portion 62 and an upper portion 64. The second barrier layer 61 may surround the doped structure 82.

FIG. 2E is cross sectional view of some of the steps in a method of manufacturing a High-Electron-Mobility-Transistor 10 according to one or more examples. In FIG. 2E, the example method may include forming a second buffer layer 45 over the recessed portion 62 of the second barrier layer 61 and may include forming the second buffer layer 45 over the upper portion 64 of the second barrier layer 61. The second buffer layer 45 may comprise a second III-V compound semiconductor such as gallium nitride.

FIG. 2F is cross sectional view of some of the steps in a method of manufacturing a High-Electron-Mobility-Transistor 10 according to one or more examples. In FIG. 2F, the example method may include forming a spacer 85 on a portion of the doped structure 82 through the second buffer layer 45 and through the upper portion 64 of the second barrier layer 61. In FIG. 2F, the example method may include forming an insulating layer 100 over the second buffer layer 45 and over a portion of the spacer 85. The insulating layer 100 may comprise polysilicon, silicon dioxide or a mixture of polysilicon and silicon dioxide. The insulating layer 100 may comprise an insulator having a K value between 1 to 3.9. In FIG. 2F, the example method may include forming a gate electrode 130 within the spacer 85 through the insulating layer 100, through the second buffer layer 45 and partially into the upper portion 64 of the second barrier layer 61. The gate electrode 130 may be connected to the doped structure 82. In FIG. 2F, the example method may include forming a drain terminal 120 at a first side of the gate electrode 130. In FIG. 2F, the example method may include forming a source terminal 110 at a second side of the gate electrode 130.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A High-Electron-Mobility-Transistor comprising:
a substrate;
a first buffer layer formed on the substrate;
a first barrier layer formed on the first buffer layer;
a doped structure formed on the first barrier layer;
a second barrier layer having a recessed portion and an upper portion, the second barrier layer formed over the first barrier layer and formed over the doped structure, wherein the second barrier layer surrounds the doped structure;
a second buffer layer formed over the recessed portion of the second barrier layer and formed over the upper portion of the second barrier layer;
a spacer formed on a portion of the doped structure through the second buffer layer and through the upper portion of the second barrier layer;
an insulating layer formed over the second buffer layer and formed over a portion of the spacer;
a gate electrode formed within the spacer through the insulating layer, through the second buffer layer and partially into the upper portion of the second barrier layer, the gate electrode connected to the doped structure;
a drain terminal formed at a first side of the gate electrode; and
a source terminal formed at a second side of the gate electrode.

2. The High-Electron-Mobility-Transistor of claim 1, wherein the substrate comprises gallium nitride, diamond, silicon carbide, sapphire, aluminum nitride or silicon.

3. The High-Electron-Mobility-Transistor of claim 1, wherein the first buffer layer comprises a first III-V compound semiconductor.

4. The High-Electron-Mobility-Transistor of claim 1, wherein the first buffer layer comprises gallium nitride.

5. The High-Electron-Mobility-Transistor of claim 1, wherein the first barrier layer comprises aluminum gallium nitride.

6. The High-Electron-Mobility-Transistor of claim 1, wherein the second barrier layer comprises aluminum gallium nitride.

7. The High-Electron-Mobility-Transistor of claim 1, wherein the doped structure comprises P-doped gallium nitride.

8. The High-Electron-Mobility-Transistor of claim 1, wherein the second buffer layer comprises a second III-V compound semiconductor.

9. The High-Electron-Mobility-Transistor of claim 1, wherein the second buffer layer comprises gallium nitride.

10. The High-Electron-Mobility-Transistor of claim 1, wherein the insulating layer comprises polysilicon, silicon dioxide or a mixture of polysilicon and silicon dioxide.

11. A method for producing a High-Electron-Mobility-Transistor comprising:
providing a substrate;
forming a first buffer layer on the substrate;
forming a first barrier layer over the first buffer layer;
forming a doped structure over the first barrier layer;
forming a second barrier layer having a recessed portion and an upper portion, the second barrier layer formed over the first barrier layer and formed over the doped structure, wherein the second barrier layer surrounds the doped structure;
forming a second buffer layer over the recessed portion of the second barrier layer and over the upper portion of the second barrier layer;
forming a spacer on a portion of the doped structure through the second buffer layer and through the upper portion of the second barrier layer;
forming an insulating layer over the second buffer layer and over a portion of the spacer;
forming a gate electrode within the spacer through the insulating layer, through the second buffer layer and partially into the upper portion of the second barrier layer, the gate electrode connected to the doped structure;
forming a drain terminal at a first side of the gate electrode; and
forming a source terminal formed at a second side of the gate electrode.

12. The method for producing a High-Electron-Mobility-Transistor of claim 11, wherein the substrate comprises gallium nitride, diamond, silicon carbide, sapphire, aluminum nitride or silicon.

13. The method for producing a High-Electron-Mobility-Transistor of claim 11, wherein the first buffer layer comprises a first III-V compound semiconductor.

14. The method for producing a High-Electron-Mobility-Transistor of claim 11, wherein the first buffer layer comprises gallium nitride.

15. The method for producing a High-Electron-Mobility-Transistor of claim 11, wherein the first barrier layer comprises aluminum gallium nitride.

16. The method for producing a High-Electron-Mobility-Transistor of claim 11, wherein the second barrier layer comprises aluminum gallium nitride.

17. The method for producing a High-Electron-Mobility-Transistor of claim 11, wherein the doped structure comprises P-doped gallium nitride.

18. The method for producing a High-Electron-Mobility-Transistor of claim 11, wherein the second buffer layer comprises a second III-V compound semiconductor.

19. The method for producing a High-Electron-Mobility-Transistor of claim 11, wherein the second buffer layer comprises gallium nitride.

20. The method for producing a High-Electron-Mobility-Transistor of claim 11, wherein the insulating layer comprises polysilicon, silicon dioxide or a mixture of polysilicon and silicon dioxide.
